(19) United States
(12) Patent Application Publication
(10) Pub. No.: US 2026/0215034 A1
(43) Pub. Date: Jul. 23, 2026

(54) METHOD FOR PRODUCING AN ELECTRONIC DEVICE

(71) Applicant: COMMISSARIAT A L'ENERGIE ATOMIQUE ET AUX ENERGIES ALTERNATIVES, Bat Le Ponant (FR)

(72) Inventors: Emilie Bourjot, Grenoble (FR); Franck Fournel, Grenoble (FR); Sophie Giroud, Grenoble (FR)

(73) Assignee: Commissariat à l'Énergie Atomique et Aux Énergies Alternatives, Bat le Ponant (FR)

(21) Appl. No.: 19/140,974

(22) PCT Filed: Dec. 14, 2023
(86) PCT No.: PCT/EP2023/085921

§ 371 Date: Jun. 18, 2025

(30) Foreign Application Priority Data
Dec. 20, 2022 (FR) FR2214008

(51) Int. Cl. H10H 20/01

(52) U.S. Cl. CPC H10H 20/0364; H10H 20/0133

(57) ABSTRACT

A method of manufacturing an electronic device including the following successive steps: a) forming a structure including a first wafer, an active stack arranged on the first wafer, and a first interconnection stack coating a surface of the active stack opposite to the first wafer; and b) transferring the structure onto a second wafer by molecular bonding on the side of a surface of the first interconnection stack opposite to the first wafer, the second wafer having a diameter greater than that of the first wafer.

### METHOD OF MANUFACTURING AN ELECTRONIC DEVICE

The present application is based on, and claims the priority of, French patent application FR2214008 filed on Dec. 20, 2022 and entitled “Procédé de réalisation d'un dispositif électronique,” which is incorporated herein by reference to the extent provided by law.

### TECHNICAL FIELD

The present disclosure generally concerns electronic devices. The present disclosure more particularly aims at methods of manufacturing electronic devices, for example optoelectronic devices comprising light-emitting diodes.

### PRIOR ART

Electronic device manufacturing methods, for example implementing substrates considered unconventional, for example substrates of relatively small dimensions and/or substrates made of sapphire or of a III-V semiconductor material, have been provided. These methods however suffer from various disadvantages.

### SUMMARY OF THE INVENTION

There is a need to improve known electronic device manufacturing methods.

For this purpose, an embodiment provides a method of manufacturing an electronic device comprising the following successive steps:
a) forming a structure comprising a first wafer, an active stack arranged on the first wafer, and a first interconnection stack coating a surface of the active stack opposite to the first wafer; and
b) transferring the structure onto a second wafer by molecular bonding on the side of a surface of the first interconnection stack opposite to the first wafer, the second wafer having a diameter greater than that of the first wafer.

According to an embodiment, the method further comprises, subsequently to step b), a step c) of dicing of the active stack and of the first interconnection stack into dies.

According to an embodiment, the method further comprises, between steps b) and c), a step of removal of the first wafer.

According to an embodiment, the method further comprises, subsequently to the step of removal of the first wafer and prior to step c), steps of deposition of a dielectric layer coating the first interconnection stack and the active stack, and of planarization of said layer.

According to an embodiment, the method further comprises, subsequently to the step of planarization of the dielectric layer and prior to step c), a step of transfer of the structure comprising the second wafer, the first interconnection stack, the active stack, and the dielectric layer onto a third wafer by molecular bonding on the side of a surface of the dielectric layer opposite to the second wafer.

According to an embodiment, the third wafer has a diameter greater than that of the first wafer.

According to an embodiment, the method further comprises, subsequently to the step of bonding to the third wafer and prior to step c), a step of removal of the second wafer.

According to an embodiment, the method further comprises, subsequently to the step of removal of the second wafer and prior to step c), a step of forming of a second interconnection stack on the side of a surface of the first interconnection stack opposite to the third wafer.

According to an embodiment, the method further comprises, subsequently to step c), a step of transfer of the dies onto a fourth wafer by molecular bonding on the side of a surface of the second interconnection stack opposite to the third wafer.

According to an embodiment, the method further comprises, subsequently to step c), a step d) of transfer of the dies onto a fifth wafer by molecular bonding on the side of a surface of the active stack opposite to the second wafer.

According to an embodiment, the method further comprises, subsequently to step d), a step of removal of the second wafer.

According to an embodiment, the method further comprises, subsequently to step d), a step e) of forming of a third interconnection stack, coating a surface of the first interconnection stack opposite to the fifth wafer.

According to an embodiment, the method further comprises, subsequently to step e), a step f) of transfer of the structure comprising the fifth wafer, the first interconnection stack, the active stack, and the third interconnection stack onto a sixth wafer by molecular bonding on the side of a surface of the third interconnection stack opposite to the second wafer.

According to an embodiment, the first wafer has a diameter equal to approximately 150 mm.

According to an embodiment, the second wafer has a diameter equal to approximately 200 or 300 mm.

According to an embodiment, the active stack is an active light-emitting diode stack.

According to an embodiment, the first wafer is made of sapphire or of an inorganic semiconductor material different from silicon, preferably of a III-V semiconductor material.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1A, FIG. 1B, FIG. 1C, FIG. 1D, FIG. 1E, FIG. 1F, and FIG. 1G are cross-section views illustrating, schematically and partially, structures obtained at the end of successive steps of an example of an optoelectronic device manufacturing method according to an embodiment;

FIG. 2A, FIG. 2B, FIG. 2C, FIG. 2D, FIG. 2E, and FIG. 2F are cross-section views illustrating, schematically and partially, structures obtained at the end of successive steps of an example of an optoelectronic device manufacturing method according to another embodiment; and

FIG. 3A and FIG. 3B are cross-section views illustrating, schematically and partially, structures obtained at the end of successive steps of a variant of the optoelectronic device manufacturing method of FIGS. 2A to 2F.

### DESCRIPTION OF EMBODIMENTS

Like features have been designated by like references in the various figures. In particular, the structural and/or functional features that are common among the various embodiments may have the same references and may dispose identical structural, dimensional and material properties.

For the sake of clarity, only those steps and elements that are useful for understanding the described embodiments have been shown and are described in detail. In particular, the forming of the light-emitting diode stacks and of their control circuits has not been detailed, the forming of such stacks and of such circuits being within the abilities of those skilled in the art based on the indications of the present description.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably plus or minus 5%.

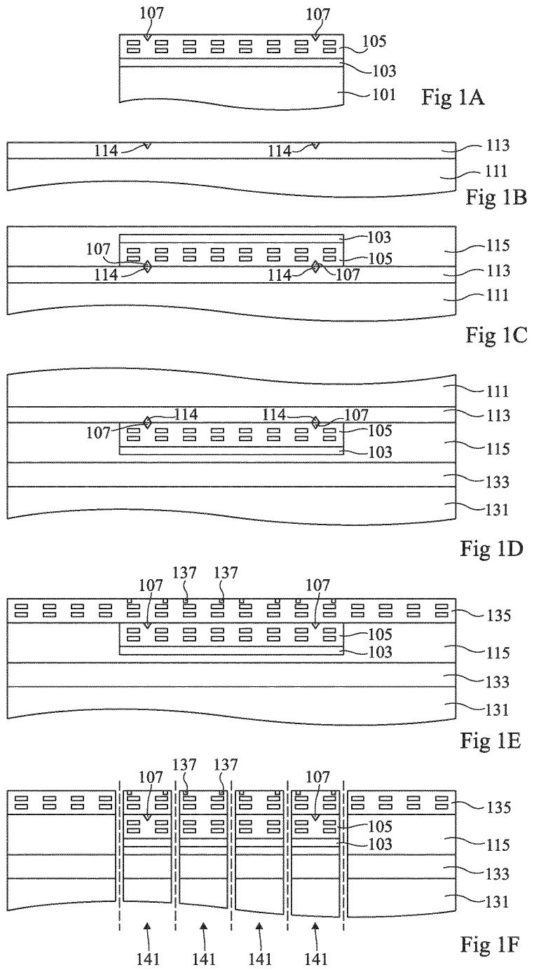

FIG. 1A, FIG. 1B, FIG. 1C, FIG. 1D, FIG. 1E, FIG. 1F, and FIG. 1G are cross-section views illustrating, schematically and partially, structures obtained at the end of successive steps of an example of an optoelectronic device manufacturing method according to an embodiment.

FIG. 1A more particularly illustrates a structure obtained at the end of a step of forming, on a surface of a wafer 101 (the upper surface of wafer 101, in the orientation of FIG. 1A), of an active stack 103, for example an active light-emitting diode stack and, on the side of a surface of active light-emitting diode stack 103 opposite to wafer 101 (the upper surface of active light-emitting diode stack 103, in the orientation of FIG. 1A), of an interconnection stack 105. By active stack, there is meant a stack of layers comprising at least one semiconductor layer, for example an emissive layer, in the case of a light-emitting diode, or a photoelectric conversion layer, in the case of a photodiode, where the active stack may further comprise one or more charge injection layers (electrons or holes) and/or one or more charge transport layers. In other electronic devices such as power diodes or transistors, the active stack corresponds, for example, to the semiconductor layers defining the PN junction of the diode, or to a layer in which a channel region of the transistor is formed.

In the shown example, wafer 101 acts as a mechanical support, or handle, and is in particular devoid of electrical functionalities. Wafer 101 is, for example, a substrate having a general disk shape. In this case, wafer 101 for example has a diameter smaller than or equal to approximately 150 mm, for example equal to approximately 150 mm. Wafer 101 is made, for example, of single-crystal silicon, of sapphire, or of an inorganic semiconductor material different from silicon, for example a III-V compound comprising at least a first group-III element, a second group-V element and, optionally, a third element, for example a group-III element other than the first element. As an example, wafer 101 is made of gallium nitride (GaN).

In the example shown in FIG. 1A, active light-emitting diode stack 103 coats the upper surface of wafer 101. Although this has not been detailed in the drawings, active light-emitting diode stack 103 comprises, for example, an active layer, or emissive layer. The active layer of light-emitting diode stack 103 is, for example, interposed between, on the one hand, a first stack comprising, for example, hole injection, hole transport, and/or electron blocking layers and, on the other hand, a second stack comprising, for example, electron injection, electron transport, and/or hole blocking layers. As an example, active light-emitting diode stack 103 is formed by epitaxy from the upper surface of wafer 101.

In the shown example, interconnection stack 105 coats the surface of active light-emitting diode stack 103 opposite to wafer 101. Interconnection stack 105 comprises, for example, alternating dielectric and conductive layers. Inside the conductive layers are for example formed electrical connection tracks and/or terminals symbolized, in FIG. 1A, by separate rectangles.

In the shown example, alignment marks 107 are formed in interconnection stack 105. Alignment marks 107 extend, for example, across the thickness of interconnection stack 105 from the upper surface of interconnection stack 105. In FIG. 1A, alignment marks 107 have been symbolized by triangles, it being understood that alignment marks 107 may, in practice, have any shape. As an example, the upper surface of stack 105 is prepared by chemical and mechanical polishing (CMP), for example, so that the surface has a nanotopography and a roughness compatible with a direct bonding.

FIG. 1B more particularly illustrates a structure obtained at the end of a step of forming, on a surface of another wafer 111 (the upper surface of wafer 111, in the orientation of FIG. 1B), of a dielectric layer 113.

In the shown example, wafer 111 acts as a mechanical support, or handle, and is in particular devoid of electrical functionalities. According to an embodiment, wafer 111 differs from the wafer 101 previously described in relation with FIG. 1A in that wafer 111 has a diameter greater than that of wafer 101. Wafer 111 for example has a diameter equal to approximately 200 or 300 mm. Wafer 111 may also be made of a material different from that of wafer 101. As an example, wafer 111 is made of single-crystal silicon.

In the orientation of FIG. 1B, dielectric layer 113 coats the upper surface of wafer 111. Dielectric layer 113 is, for example, made of an oxide such as silicon dioxide (SiO₂). As an example, dielectric layer 113 is first deposited on wafer 111 and then planarized, for example by chemical-mechanical polishing, so that its surface opposite to wafer 111 (the upper surface of layer 113, in the orientation of FIG. 1B) has a topography adapted to the subsequent implementation of a molecular bonding.

In the shown example, alignment marks 114 are formed in dielectric layer 113. Alignment marks 114 extend, for example, across the thickness of dielectric layer 113 from the upper surface of layer 113. In FIG. 1B, alignment marks 114 have been symbolized by triangles, it being understood that alignment marks 114 may, in practice, have any shape.

FIG. 1C more particularly illustrates a structure obtained at the end of subsequent steps of transfer of the structure previously described in relation with FIG. 1A onto the structure previously described in relation with FIG. 1B, of removal of wafer 101, and of deposition of a dielectric layer 115.

As an example, the structure previously described in relation with FIG. 1A is turned over with respect to the orientation of FIG. 1A and then brought into contact, by the surface of interconnection stack 105 opposite to wafer 101 (the lower surface of interconnection stack 105, in the orientation of FIG. 1C), with dielectric layer 113. During this step, the structure comprising wafer 101, active light-emitting diode stack 103, and interconnection stack 105 is bonded to wafer 111. As an example, the bonding to wafer 111 is achieved by molecular bonding between the two surfaces brought into contact. In a preliminary step, the surfaces of layers 115 and 133 are for example prepared so as to be made compatible with the bonding method.

During the bonding, the structure previously described in relation with FIG. 1A is, for example, aligned with respect to the structure previously described in relation with FIG. 1B with an alignment accuracy in the order of 100 μm. More precisely, during this step, alignment marks 107 are aligned with respect to alignment marks 114.

For example, wafer 101 is removed by grinding, by wet etching or, in the case where wafer 101 is made of sapphire, by a laser lift-off (LLO) technique.

Once wafer 101 has been removed, dielectric layer 115 is for example deposited on the structure on the side of the surface of dielectric layer 113 opposite to wafer 111 (the upper surface of dielectric layer 113, in the orientation of FIG. 1C). Dielectric layer 115 is then planarized, for example by chemical-mechanical polishing, so that its upper surface has a topography adapted to the subsequent implementation of a molecular bonding. In the shown example, dielectric layer 115 coats portions of dielectric layer 113 which are not coated with interconnection stack 105, the flanks of interconnection stack 105, and the flanks and the upper surface of active light-emitting diode stack 103. As an example, dielectric layer 115 is made of the same material as dielectric layer 113, for example silicon dioxide.

FIG. 1D more particularly illustrates a structure obtained at the end of a subsequent step of transfer of the structure previously described in relation to FIG. 1C onto a structure comprising a wafer 131 coated, on one of its surfaces (the upper surface of wafer 131, in the orientation of FIG. 1D), with a dielectric layer 133. Wafer 131 and dielectric layer 133 are, for example, identical or similar, respectively, to the wafer 111 and to the dielectric layer 113 previously described in relation with FIG. 1B.

As an example, the structure previously described in relation with FIG. 1C is turned over with respect to the orientation of FIG. 1C and then brought into contact, by the surface of dielectric layer 115 opposite to wafer 111 (the lower surface of dielectric layer 115, in the orientation of FIG. 1D), with dielectric layer 133. During this step, the structure previously described in relation with FIG. 1C is bonded to wafer 131. As an example, the bonding to wafer 131 is achieved by molecular bonding between the two surfaces brought into contact.

During the bonding step, the structure previously described in relation with FIG. 1C is for example aligned with respect to wafer 131 with an alignment accuracy in the range from 2 to 50 μm.

FIG. 1E more particularly illustrates a structure obtained at the end of subsequent steps of removal of wafer 111 and of dielectric layer 113, and of forming of interconnection stack 135.

As an example, wafer 111 is removed by grinding, by wet chemical etching, or by a laser separation technique. Dielectric layer 113 is for example first partially removed by grinding, after which the remaining portion of dielectric layer 113 is removed by chemical-mechanical polishing so as to avoid any risk of damage to interconnection stack 105.

In the shown example, the surface of dielectric layer 115 opposite to wafer 131 (the upper surface of dielectric layer 115, in the orientation of FIG. 1E), is flush with the surface of interconnection stack 105 opposite to wafer 131 (the upper surface of interconnection stack 105, in the orientation of FIG. 1E).

In the example shown in FIG. 1E, interconnection stack 135 covers the surfaces of interconnection stack 105 and of dielectric layer 115 opposite to wafer 131 (the upper surfaces of interconnection stack 105 and of dielectric layer 115 in the orientation of FIG. 1E). Interconnection stack 135 comprises, for example, alternating dielectric layers, for example made of silicon dioxide, and conductive layers, for example made of copper, inside of which are formed electrical connection tracks and/or terminals symbolized, in FIG. 1E, by separate rectangles.

As an example, interconnection stack 135 is formed by the implementation of steps of a “damascene” type method. Interconnection stack 135 is, in the shown example, aligned with respect to the alignment marks 107 previously formed in interconnection stack 105. This enables in particular to ascertain that the electrical connection tracks and/or terminals of interconnection stack 135 are connected to the connection tracks and/or terminals of the underlying interconnection stack 105.

In the shown example, alignment marks 137 are formed in interconnection stack 135. Alignment marks 137 extend, for example, across the thickness of interconnection stack 135 from a surface of interconnection stack 135 opposite to wafer 131 (the upper surface of stack 135, in the orientation of FIG. 1E). In FIG. 1E, alignment marks 137 have been symbolized by squares, it being understood that alignment marks 137 may, in practice, have any shape.

FIG. 1F more particularly illustrates a structure obtained at the end of an optional subsequent step of dicing, across its entire thickness, of the structure previously described in relation with FIG. 1E so as to form dies 141.

In the shown example, each die 141 comprises a portion of wafer 131 and a stack comprising, in the order from wafer 131, a portion of dielectric layer 133, a portion of dielectric layer 115, a portion of active light-emitting diode stack 103, a portion of interconnection stack 105, and a portion of interconnection stack 135.

As an example, each die 141 has, in top view, a substantially rectangular or square perimeter and a surface area in the range from a few square micrometers to a few square centimeters.

Although four dies 141 have been shown in FIG. 1F, the dicing step may of course lead to the forming of a number of dies 141 other than four, for example several tens or several hundreds of dies 141. Each die 141 corresponds, for example, to an elementary light-emitting diode, that is, a light-emitting diode controllable independently of other light-emitting diodes.

In the case where the dicing step is implemented, the alignment marks 137 formed in interconnection stack 135 are more precisely “die to wafer” (DTW) alignment marks. In the opposite case, that is, if the structure previously described in relation with FIG. 1E is not diced into individual wafers 141, this structure being intended, for example, to be transferred as it is onto another wafer, the alignment marks 137 are more precisely “wafer to wafer” (WTW) alignment marks.

As an example, the upper surface of layer 135 is pre-prepared so as to be made compatible with hybrid bonding operations.

In particular, FIG. 1G illustrates a structure obtained at the end of a step of transfer of dies 141 onto a structure comprising a wafer 151, an active region 153, for example formed inside and on top of wafer 151, and an interconnection stack 155 coating a surface of active region 153 opposite to wafer 151 (the upper surface of active region 153, in the orientation of FIG. 1G).

Wafer 151 is for example similar or identical to wafers 111 and 131.

Although this has not been detailed in FIG. 1G, active region 153 comprises, for example, transistors for controlling dies 141, for example, transistors intended to control the portion of the active light-emitting diode stack 103 of each die 141.

Interconnection stack 155 for example comprises alternating dielectric layers, for example made of silicon dioxide, and conductive layers, for example made of copper, inside which are formed electrical connection tracks and/or terminals symbolized, in FIG. 1G, by separate rectangles. As an example, the upper surface of interconnection stack 155 is pre-prepared so as to have a nanotopography compatible with hybrid molecular bonding, for example implementing copper/oxide surfaces.

Wafer 151, active region 153, and interconnection stack 155 for example form a substrate 157 of CMOS (Complementary Metal-Oxide-Semiconductor) type.

As an example, the dies 141 previously described in relation with FIG. 1F are turned over with respect to the orientation of FIG. 1F and then brought into contact, by the surface of interconnection stack 135 opposite to wafer 131 (the lower surface of interconnection stack 135, in the orientation of FIG. 1G), with interconnection stack 155. During this step, dies 141 are bonded to wafer 151. As an example, the bonding to wafer 151 is achieved by molecular bonding between the two surfaces brought into contact. The transfer of dies 141 onto wafer 151 is for example performed by a “pick and place” method, each die being transferred individually, or by a collective transfer method.

During the bonding step, dies 141 are for example aligned with respect to wafer 151 with an alignment accuracy in the range from 500 nm to 1.5 μm, for example equal to approximately 700 nm. To achieve this, alignment marks 159, for example similar or identical to alignment marks 137, are formed in interconnection stack 155, on the side of a surface of interconnection stack 155 opposite to wafer 151. In FIG. 1G, alignment marks 159 have been symbolized by squares, it being understood that alignment marks 159 may, in practice, have any shape. During the alignment operation, the alignment marks 137 of dies 141 are substantially aligned with respect to the alignment marks 159 of CMOS substrate 157. This enables in particular to ascertain that the electrical connection tracks and/or terminals of interconnection stack 135, and thus the electrical connection tracks and/or terminals of interconnection stack 105, are connected to the connection tracks and/or terminals of the underlying interconnection stack 155.

As a variant, in the case where the dicing step previously described in relation with FIG. 1F is omitted, the structure previously described in relation with FIG. 1E is, for example, transferred, by molecular bonding, onto CMOS substrate 157 in a way similar to that which is discussed hereabove for dies 141.

An advantage of the method previously described in relation with FIGS. 1A to 1G is that it enables, to form the interconnection stack 155 of CMOS substrate 157, to use very precise lithography techniques enabling, in particular, to overcome constraints relative to the precise alignment of dies 141, or of the structure of FIG. 1E, with respect to CMOS substrate 157.

It could have been devised to replace wafer 101, which has lateral dimensions smaller than those of wafer 111, with a wafer made of a material different from silicon, for example sapphire or a III-V semiconductor material, and having lateral dimensions substantially equal to those of wafer 111. This would however require costly, time-consuming and non-environmentally friendly technological developments to enable the forming of active light-emitting diode stack 103 on such a substrate. Further, it could have been devised to transfer the structure shown in FIG. 1A onto a wafer similar to wafer 111, but having dimensions substantially equal to those of wafer 101. However, existing molecular bonding methods require prior planarization steps, which are currently incompatible with wafers having a diameter smaller than or equal to 150 mm.

Subsequent steps of the optoelectronic device manufacturing method may then be implemented based on the structure shown in FIG. 1G, CMOS substrate 157 being for example intended to be retained at the end of these steps.

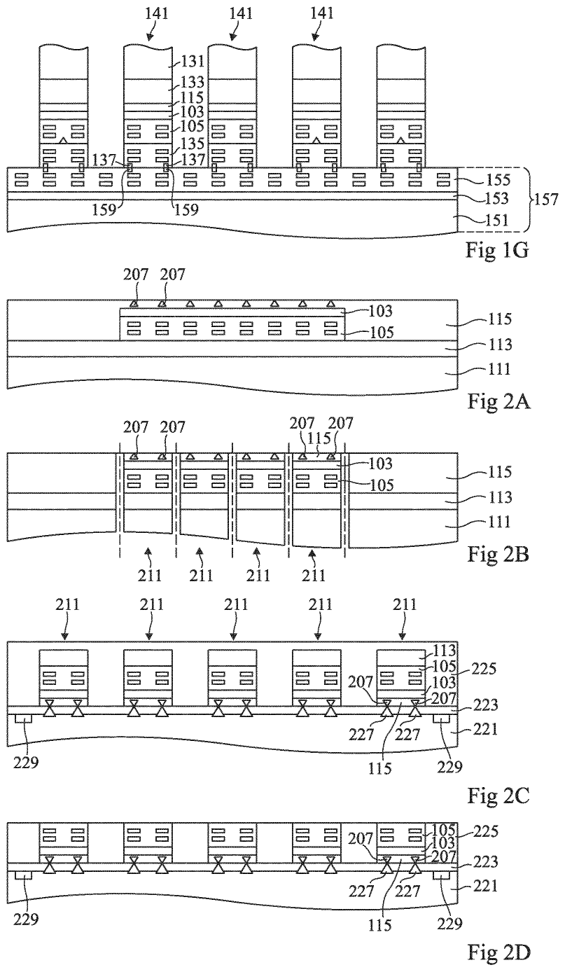

FIG. 2A, FIG. 2B, FIG. 2C, FIG. 2D, FIG. 2E, and FIG. 2F are cross-section views illustrating, schematically and partially, structures obtained at the end of successive steps of an example of an optoelectronic device manufacturing method according to another embodiment.

FIG. 2A more particularly illustrates a structure obtained at the end of steps identical or similar to the steps previously described in relation with FIGS. 1A to 1C. Although this has not been shown in FIG. 2A so as not to overload the drawing, the structure features, for example, the alignment marks 107 and 114 previously described in relation with FIGS. 1A and 1B.

The structure illustrated in FIG. 2A differs from the structure illustrated in FIG. 1C in that the structure illustrated in FIG. 2A further comprises alignment marks 207 formed in dielectric layer 115.

In the shown example, alignment marks 207 are formed on the side of a surface of dielectric layer 115 opposite to wafer 111. Alignment marks 207 are, for example, positioned and aligned according to the position of the electrical connection tracks and/or terminals of interconnection stack 105. In FIG. 2A, alignment marks 207 have been symbolized by triangles, it being understood that alignment marks 207 may, in practice, have any shape.

FIG. 2B more particularly illustrates a structure obtained at the end of a subsequent step of dicing, across its entire thickness, of the structure previously described in relation with FIG. 2A so as to form dies 211.

In the shown example, each die 211 comprises a portion of wafer 111 and a stack comprising, in this order, from wafer 111, a portion of dielectric layer 113, a portion of interconnection stack 105, a portion of active light-emitting diode stack 103, and a portion of dielectric layer 115.

As an example, each die 211 has, in top view, a substantially rectangular or square perimeter and a surface area in the range from a few square micrometers to a few square millimeters.

Although four dies 211 have been shown in FIG. 2B, the dicing step may of course lead to the forming of a number of dies 211 different from four, for example several tens or several hundreds of dies 211. Each die 211 corresponds, for example, to an elementary light-emitting diode, that is, a light-emitting diode controllable independently of other light-emitting diodes.

FIG. 2C more particularly illustrates a structure obtained after subsequent steps of:
transfer of dies 211 onto a structure comprising a wafer 221 coated, on one of its surfaces (the upper surface of wafer 221, in the orientation of FIG. 2C), with a dielectric layer 223;
removal of wafer 111; and
deposition of another dielectric layer 225.

Wafer 221 and dielectric layer 223 are, for example, similar, respectively, to the wafer 111 and to the dielectric layer 113 previously described in relation with FIG. 1B. For example, dielectric layer 223 is made of silicon dioxide.

As an example, the dies 211 previously described in relation with FIG. 2B are turned over with respect to the orientation of FIG. 2B and then brought into contact, by the surface of dielectric layer 115 opposite to wafer 111 (the lower surface of dielectric layer 115, in the orientation of FIG. 2C), with dielectric layer 223. During this step, dies 211 are bonded to wafer 221. As an example, the bonding to wafer 221 is achieved by molecular bonding between the two surfaces brought into contact.

During the bonding step, dies 211 are for example aligned with respect to alignment marks 227 previously formed in dielectric layer 223, so that the alignment marks 207 of dies 211 are positioned substantially opposite alignment marks 227. As an example, the alignment accuracy of dies 211 relative to wafer 221 is in the range from 2 to 50 μm.

As an example, wafer 111 is removed by grinding, by wet chemical etching, or by laser separation.

Once wafer 111 has been removed, dielectric layer 225 is for example deposited on the structure on the side of the surface of dielectric layer 223 opposite to wafer 221 (the upper surface of dielectric layer 223, in the orientation of FIG. 2C). Dielectric layer 225 is then planarized, for example by chemical-mechanical polishing, so that its upper surface has a topography adapted to the subsequent implementation of a molecular bonding. In the shown example, dielectric layer 225 coats portions of the dielectric layer 223 not coated with dies 211, as well as the flanks and the upper surface of each die 211. As an example, dielectric layer 225 is made of the same material as dielectric layer 223, for example silicon dioxide.

In the shown example, wafer 221 comprises alignment marks 229. In the orientation of FIG. 2C, alignment marks 229 extend vertically across the thickness of wafer 221 from its upper surface.

FIG. 2D more particularly illustrates a structure obtained at the end of a subsequent step of planarization of the structure previously described with FIG. 2C on the side of a surface of the structure opposite to wafer 221 (the upper surface of the structure, in the orientation of FIG. 2C).

As an example, dielectric layers 225 and 113 are planarized first by grinding, then by chemical-mechanical polishing. As a result of these operations, the surface of dielectric layer 225 opposite to wafer 211 (the upper surface of layer 225, in the orientation of FIG. 2D) is flush with the surface of interconnection stack 105 opposite to wafer 211 (the upper surface of interconnection stack 105, in the orientation of FIG. 2D).

FIG. 2E more particularly illustrates a structure obtained at the end of a subsequent step of forming of an interconnection stack 235.

In the example shown in FIG. 2E, interconnection stack 235 covers the surfaces of interconnection stack 105 and of dielectric layer 225 opposite to wafer 221 (the upper surfaces of interconnection stack 105 and of dielectric layer 225 in the orientation of FIG. 2E). Interconnection stack 235 comprises, for example, alternating dielectric layers, for example, made of silicon dioxide, and conductive layers, for example, made of copper, inside which are formed electrical connection tracks and/or terminals symbolized, in FIG. 2E, by separate rectangles.

As an example, interconnection stack 235 is formed by the implementation of steps of a “damascene” type method. Interconnection stack 235 is, in the shown example, aligned with respect to the alignment marks 229 previously formed in wafer 221. This enables in particular to ascertain that the electrical connection tracks and/or terminals of interconnection stack 235 are connected to the connection tracks and/or terminals of the underlying interconnection stack 105.

In the shown example, alignment marks 237 are formed in interconnection stack 235, on the side of a surface of interconnection stack 235 opposite to wafer 221. In FIG. 2E, alignment marks 237 have been symbolized by stars, it being understood that alignment marks 237 may, in practice, have any shape.

FIG. 2F more particularly illustrates a structure obtained at the end of a subsequent step of transfer, onto the structure previously described in relation with FIG. 2E, of the CMOS substrate 157 previously described in relation with FIG. 1G.

As an example, CMOS substrate 157 is brought into contact, by the surface of interconnection stack 155 opposite to wafer 151 (the lower surface of interconnection stack 155, in the orientation shown in FIG. 2F), with interconnection stack 235. During this step, CMOS substrate 157 is bonded to wafer 221. As an example, the bonding to wafer 221 is achieved by molecular bonding between the two surfaces brought into contact.

During the bonding step, CMOS substrate 157 is, for example, aligned with respect to the structure previously described in relation with FIG. 2E. For this purpose, alignment marks 247 are, for example, previously formed in interconnection stack 155 so that, at the end of the transfer step, alignment marks 247 are located substantially opposite alignment marks 237. CMOS substrate 157 is, for example, as shown in FIG. 2F, devoid of alignment marks 159.

The method described hereabove in relation with FIGS. 2A to 2F has advantages similar to the method described hereabove in relation with FIGS. 1A to 1G. In particular, the method of FIGS. 2A to 2F particularly enables to avoid the disadvantages associated with the developing of a method of forming a light-emitting diode stack on a wafer with a diameter greater than 150 mm, for example in the order of 200 or 300 mm. The method of FIGS. 2A to 2F further enables to implement a molecular bonding of active light-emitting diode stack 103 to CMOS substrate 157.

Subsequent steps in the optoelectronic device manufacturing method can then be implemented based on the structure illustrated in FIG. 2F, CMOS substrate 157, for example, being retained at the end of these steps.

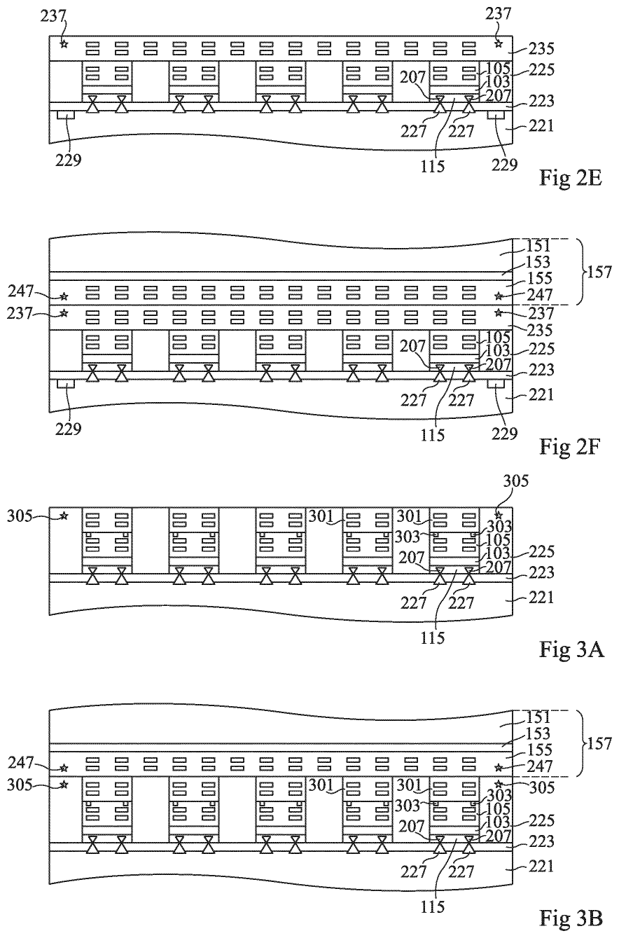

FIG. 3A and FIG. 3B are cross-section views illustrating, schematically and partially, structures obtained at the end of successive steps of a variant of the optoelectronic device manufacturing method of FIGS. 2A to 2F.

FIG. 3A more particularly illustrates a structure obtained at the end of a step of forming, from a structure similar to that previously described in relation with FIG. 2C, of interconnection stacks 301 respectively located vertically in line with dies 211.

As an example, openings extending from the upper surface of dielectric layer 225 to the interconnection stack 105 of each die 211 are first formed vertically in line with each die 211. Interconnection stacks 301, for example, are then formed inside the openings, vertically in line with dies 211. Interconnection stacks 301 are, in the shown example, aligned with respect to the alignment marks 303 previously formed in interconnection stack 105. This enables in particular to ascertain that the electrical connection tracks and/or terminals of interconnection stack 301 are connected to the connection tracks and/or terminals of the underlying interconnection stack 105.

In the shown example, wafer 221 is devoid of alignment marks 229 and alignment marks 305 are formed in dielectric layer 225. In FIG. 3A, alignment marks 305 have been symbolized by stars, it being understood that alignment marks 305 may, in practice, have any shape.

FIG. 3B more particularly illustrates a structure obtained at the end of a subsequent step of transfer, onto the structure previously described in relation with FIG. 3A, of the CMOS substrate 157 previously described in relation with FIG. 1G.

As an example, CMOS substrate 157 is brought into contact, by the surface of interconnection stack 155 opposite to wafer 151 (the lower surface of interconnection stack 155, in the orientation of FIG. 2F), with interconnection stacks 301 and the upper surface of layer 225. During this step, CMOS substrate 157 is bonded to wafer 221. As an example, the bonding to wafer 221 is achieved by molecular bonding between the two surfaces brought into contact.

During the bonding step, CMOS substrate 157 is aligned, for example, with respect to the structure previously described in relation with FIG. 3A. For this purpose, alignment marks 247 are, for example, previously formed in interconnection stack 155 so that, at the end of the transfer step, alignment marks 247 are located substantially opposite alignment marks 305. CMOS substrate 157 is, for example, as shown in FIG. 3B, devoid of alignment marks 159.

Subsequent steps in the optoelectronic device manufacturing method can then be implemented based on the structure illustrated in FIG. 3B, CMOS substrate 157 being for example intended to be retained at the end of these steps.

Various embodiments and variants have been described. Those skilled in the art will understand that certain features of these various embodiments and variants may be combined, and other variants will occur to those skilled in the art. Although embodiments have been described hereabove in relation with an example of embodiment of an optoelectronic device comprising a diode stack, the embodiments of the present disclosure more generally apply to any method of manufacturing an electronic device using a substrate considered unconventional, for example a substrate having a diameter smaller than or equal to approximately 150 mm and/or a substrate made of sapphire or of an inorganic semiconductor material other than silicon, for example a III-V semiconductor material.

Finally, the practical implementation of the described embodiments and variants is within the abilities of those skilled in the art based on the functional indications given hereabove. In particular, the described embodiments are not limited to the specific examples of materials and dimensions mentioned in the present disclosure.

1. Electronic device manufacturing method comprising the following successive steps:
a) forming a structure comprising a first wafer, an active stack arranged on the first wafer, and a first interconnection stack coating a surface of the active stack opposite to the first wafer; and
b) transferring the structure onto a second wafer by molecular bonding on the side of a surface of the first interconnection stack opposite to the first wafer, the second wafer having a diameter greater than that of the first wafer,
the method further comprising, subsequently to step b), a step c) of dicing of the active stack and of the first interconnection stack into dies.

2. Method according to claim 1, further comprising, between steps b) and c), a step of removal of the first wafer.

3. Method according to claim 2, further comprising, subsequently to the step of removal of the first wafer and prior to step c), steps of deposition of a dielectric layer coating the first interconnection stack and the active stack and of planarization of said layer.

4. Method according to claim 3, further comprising, subsequently to the step of planarization of the dielectric layer and prior to step c), a step of transfer of the structure comprising the second wafer, the first interconnection stack, the active stack, and the dielectric layer onto a third wafer by molecular bonding on the side of a surface of the dielectric layer opposite to the second wafer.

5. Method according to claim 4, wherein the third wafer has a diameter greater than that of the first wafer.

6. Method according to claim 4, further comprising, subsequently to the step of bonding to the third wafer and prior to step c), a step of removal of the second wafer.

7. Method according to claim 6, further comprising, subsequently to the step of removal of the second wafer and prior to step c), a step of forming of a second interconnection stack on the side of a surface of the first interconnection stack opposite to the third wafer.

8. Method according to claim 7, further comprising, subsequently to step c), a step of transfer of the dies onto a fourth wafer by molecular bonding on the side of a surface of the second interconnection stack opposite to the third wafer.

9. Method according to claim 1, further comprising, subsequently to step c), a step d) of transfer of the dies onto a fifth wafer by molecular bonding on the side of a surface of the active stack opposite to the second wafer.

10. Method according to claim 9, further comprising, subsequently to step d), a step of removal of the second wafer.

11. Method according to claim 10, further comprising, subsequently to step d), a step e) of forming of a third interconnection stack, coating a surface of the first interconnection stack opposite to the fifth wafer.

12. Method according to claim 11, further comprising, subsequently to step e), a step f) of transfer of the structure comprising the fifth wafer, the first interconnection stack, the active stack, and the third interconnection stack onto a sixth wafer by molecular bonding on the side of a surface of the third interconnection stack opposite to the second wafer.

13. Method according to claim 1, wherein the first wafer has a diameter equal to approximately 150 mm.

14. Method according to claim 1, wherein the second wafer has a diameter equal to approximately 200 or 300 mm.

15. Method according to claim 1, wherein the active stack is an active light-emitting diode stack.

16. Method according to claim 1, wherein the first wafer is made of sapphire or of an inorganic semiconductor material different from silicon, preferably of a III-V semiconductor material.
